(19) United States
(12) Patent Application Publication
(10) Pub. No.: US 2007/0040287 A1
(43) Pub. Date: Feb. 22, 2007

(54) Method for forming capacitor in a semiconductor device

(76) Inventor: Jong Bum Park, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/504,274

(22) Filed: Aug. 15, 2006

(30) Foreign Application Priority Data
Aug. 18, 2005 (KR) 10-2005-0075791

(51) Int. Cl. H01L 21/8242

(52) U.S. Cl. 257/E21.014; 438/240; 257/E27.104

(57) ABSTRACT

A method for forming a capacitor of a semiconductor device ensures charging capacity and improves leakage current characteristic. In the capacitor forming method, a semiconductor substrate formed with a storage node contact is prepared first. Next, a storage electrode is formed such that the storage electrode is connected to the storage node contact. Also, a dielectric film comprised of a composite dielectric of a SrTiO3 film and an anti-crystallization film is formed on the storage electrode. Finally, a plate electrode is formed on the dielectric film.

### FIELD OF THE INVENTION

The present invention relates to a method for forming a capacitor in a semiconductor device. More particularly, the present invention relates to a method for forming a capacitor in a semiconductor device, by which desired charging capacity as well as an improved leakage current characteristic can be ensured.

### BACKGROUND OF THE INVENTION

The complexity and the integration density of semiconductor devices products has increased owing to the development of semiconductor manufacturing technology. As complexity and density of semiconductors in general have increased, unit cell area has greatly decreased and operating voltage has also become lower. This causes a problem in that a memory device has a shortened refresh time and soft errors occur. To prevent this problem, there is always a desire to develop a capacitor in which high charging capacity greater than 25 fF/cell is obtained, and only small leakage current is generated.

As is well known in the art, the charging capacity of a capacitor is proportional to electrode surface area and the dielectric constant of a dielectric film, and is inversely proportional to dielectric film thickness corresponding to a distance between electrodes, more precisely, the equivalent SiO2 thickness (Tox) of the dielectric film. For realizing high charging capacity required for a highly integrated device, therefore, it is indispensable to use a dielectric film having a high dielectric constant and capable of lowering the equivalent SiO2 thickness.

A conventional capacitor using a Si3N4 (ε=7) thin film as a dielectric film has a limitation on ensuring charging capacity, and thus, research is being pursued to ensure sufficient charging capacity by applying various kinds of dielectric films having a greater dielectric constant than that of Si3N4 (ε=7) to a capacitor.

As a part of such research, a MIM-type capacitor has recently been proposed, which can be applied to DRAM devices with a line width of 70 nm or less by employing a SrTiO3 dielectric film having a high dielectric constant. The SrTiO3 dielectric film, a material having a very high dielectric constant of 100 to 150, is being spotlighted as a dielectric film capable of charging capacity required for next generation DRAM devices.

Although the SrTiO3 dielectric film is advantageous to ensure charging capacity, it also has a disadvantage in that the SrTiO3 film is crystallized in a deposition process even when deposited at comparatively low temperature according to an Atomic Layer Deposition (hereinafter referred to as “ALD”) method, which causes deterioration in its leakage current characteristic.

That is, in a case of the capacitor employing the SrTiO3 dielectric film, there occur problems fatal to device operation in that charged electric charge is leaked in a short time to thereby shorten the refresh time of the device, and others. Therefore, the problem of leakage current must be overcome in order to actually apply the SrTiO3 dielectric film to semiconductor devices.

### SUMMARY OF THE INVENTION

Accordingly, an object of the present invention is to provide a method for manufacturing a capacitor of a semiconductor device, which can suppress leakage current occurrence in a SrTiO3 dielectric film when a capacitor, to which the SrTiO3 dielectric film is applied. In order to accomplish this object, there is provided both a semiconductor device having a capacitor with a reduce or suppressed leakage, and a method for manufacturing a semiconductor having such a capacitor, the method comprising the steps of: preparing a semiconductor substrate formed with a storage node contact; forming a storage electrode such that the storage electrode is connected to the storage node contact; forming a dielectric film composed of a composite dielectric of a SrTiO3 film and an anti-crystallization film on the storage electrode; and forming a plate electrode on the dielectric film.

Here, the dielectric film composed of the composite dielectric of the SrTiO3 film and the anti-crystallization film is deposited within one chamber, and is formed in a thickness of 20 to 200 Å.

The anti-crystallization film is preferably an Al2O3 film or a SiO2 film.

At this time, the dielectric film composed of the composite dielectric of the SrTiO3 film and the Al2O3 film is deposited at a pressure ranging from 0.1 to 10 Torr and at a temperature ranging from 200 to 500° C. according to an ALD process.

Also, the dielectric film composed of the composite dielectric of the SrTiO3 film and the SiO2 film is deposited at a pressure ranging from 0.1 to 10 Torr and at a temperature ranging from 25 to 500° C. according to an ALD process.

The dielectric film composed of the composite dielectric of the SrTiO3 film and the Al2O3 film may be deposited by repeatedly performing a SrO thin film deposition cycle x including a Sr source gas flowing step, a purging step, a reaction gas flowing step and a purging step, a TiO2 thin film deposition cycle y including a Ti source gas flowing step, a purging step, a reaction gas flowing step and a purging step, and an Al2O3 thin film deposition cycle z including an Al source gas flowing step, a purging step, a reaction gas flowing step and a purging step, according to the ALD process, in such a manner that the z cycle. and the (x+y) cycle are alternately repeated after the SrTiO3 thin film is deposited through the (x+y) cycle, or the (x+y) cycle and the z cycle are alternately repeated after the Al2O3 thin film is deposited through the z cycle.

Also, the dielectric film composed of the composite dielectric of the SrTiO3 film and the SiO2 film may be deposited by repeatedly performing a SrO thin film deposition cycle x′ including a Sr source gas flowing step, a purging step, a reaction gas flowing step and a purging step, a TiO2 thin film deposition cycle y′ including a Ti source gas flowing step, a purging step, a reaction gas flowing step and a purging step, and an SiO2 thin film deposition cycle z including an Si source gas flowing step, a purging step, a reaction gas flowing step and a purging step, according to the ALD process, in such a manner that the z′ cycle and the (x′+y′) cycle are alternately repeated after the SrTiO3 thin film is deposited through the (x′+y′) cycle, or the (x′+y′) cycle and the z cycle are alternately repeated after the SiO2 thin film is deposited through the z′ cycle.

Here, each of the (x+y) cycle, the z cycle, the (x′+y′) cycle and the z′ cycle may be repeated one to five times.

Sr(thd)2THF2 may be used as the Sr source gas, Ti(OiPr)4 or Ti(EtO)4 may be used as the Ti source gas, and N2 or Ar may be used as the purging gas.

Preferably, the Sr source gas, the Ti source gas and the purging gas are flowed for 0.1 to 10 seconds, respectively.

In the Al2O3 thin film deposition cycle, Al(CH3)3(Tri-Methyl Aluminum: TMA) may be used as the Al source gas, and any one selected from the group composed of O3, plasma O2 and H2O vapor may be used as the reaction gas. At this time, the Al source gas is flowed for 0.1 to 5 seconds, and the reaction gas is flowed for 0.1 to 10 seconds.

In addition, in the SiO2 thin film deposition cycle, SiCl4(Tetra-Chloride Silicon: TCS) or Si2Cl6(Hexa-Chloro Disilane: HCD) may be used as the Si source gas, and H2O vapor may be used as the reaction gas. At this time, the Si source gas and the reaction gas are flowed for 0.1 to 10 seconds, respectively.

The inventive method for forming a capacitor may further comprise an O3 treatment step and a purging step for the deposited film, which are performed whenever each deposition cycle (x, y, z, x′, y′ or z′ cycle) terminates during the dielectric film deposition step. At this time, the O3 treatment is performed for 0.1 to 10 seconds, and the purging step is performed in a manner of flowing N2 or Ar gas for 0.1 to 5 seconds.

Further, the inventive method for forming a capacitor may comprise an O3 treatment step and a purging step for the deposited film, which are performed whenever each unit process comprising the three deposition cycles (x, y and z cycles or x′, y′ and z′ cycles) terminates during the dielectric film deposition step. At this time, the O3 treatment is performed for 5 to 300 seconds, and the purging step is performed in a manner of flowing N2 or Ar gas for 0.1 to 5 seconds.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1C are process-by-process sectional views for explaining a method for forming a capacitor of a semiconductor device in accordance with a preferred embodiment of the present invention; and

FIG. 2 is a view for explaining a dielectric film deposition process according to the present invention.

### DETAILED DESCRIPTION OF THE PREFERRED EMBODIMENTS

Hereinafter, preferred embodiments of the present invention will be described with reference to the accompanying drawings. In the following description and drawings, the same reference numerals are used to designate the same or similar components, and so repetition of the description on the same or similar components will be omitted.

For the sake of obtaining charging capacity and leakage current characteristics required for a DRAM capacitor with a line width of 70 nm or less, the present invention proposes a capacitor, which employs a dielectric film composed of a composite dielectric of a SrTiO3 film and an anti-crystallization film (Al2O3 film or SiO2 film) for the SrTiO3 film.

When such a dielectric film is employed, not only can the charging capacity characteristic required for a DRAM capacitor with a line width of 70 nm or less be ensured in connection with the fact that the SrTiO3 film has a very high dielectric constant of 100 to 150, but leakage current in the SrTiO3 film can also be reduced or effectively suppressed because the anti-crystallization film (Al2O3 film or SiO2 film), which is not crystallized under high-temperature heat treatment conditions, prevents the crystallization of the SrTiO3 film.

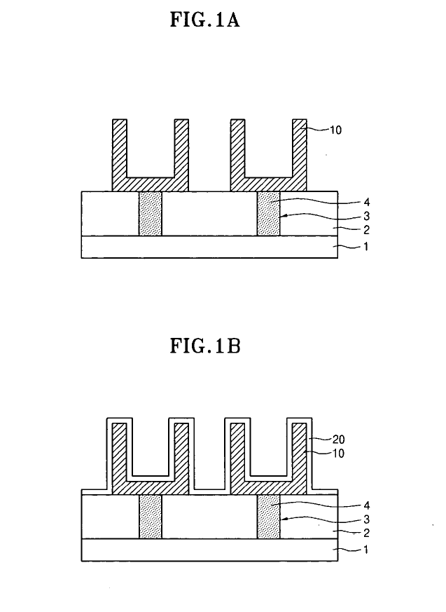

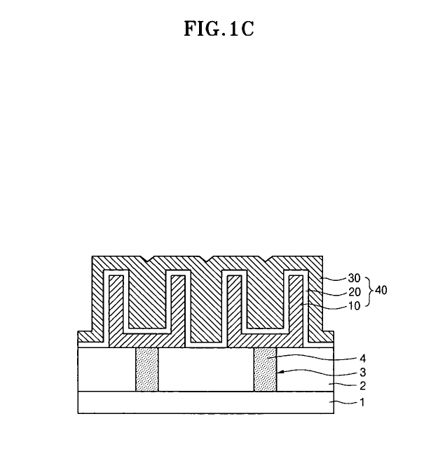

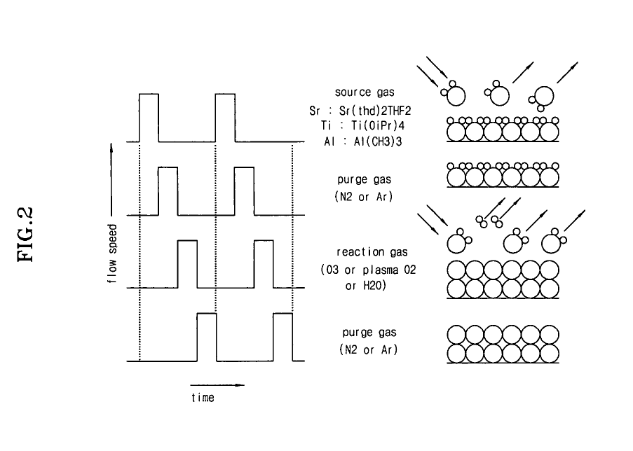

Hereinafter, this will be described in detail with reference to FIGS. 1A to 1C, which illustrate process-by-process sectional views for explaining the inventive method for forming a capacitor of a semiconductor device.

Referring to FIG. 1A, an interlayer insulating film 2 is formed on the entire surface of a semiconductor substrate 1, which is formed with lower patterns (not shown) including a transistor and a bit line, such that the interlayer insulating film 2 covers the lower patterns. Next, the interlayer insulating film 2 is etched to form a contact hole 3, through which a substrate junction area or a Landing Plug Poly (LPP) is exposed, and then the contact hole 3 is filled with an electrically conductive film to form a storage node contact 4. Subsequently, a storage electrode 10 is formed on the interlayer insulating film 2, including the storage node contact 4, such that the storage electrode 10 is electrically connected to the storage node contact 4.

In FIG. 1A, the storage electrode 10 has a substantially cylindrical structure, but in alternate embodiments it may be formed to have a concave structure or a simple plate structure.

Referring to FIG. 1B, a dielectric film 20 is composed of a composite dielectric of a SrTiO3 film and an anti-crystallization film (Al2O3 film or SiO2 film) is formed on the storage electrode 10.

The SrTiO3 film and the anti-crystallization film (Al2O3 film or SiO2 film) are formed at a pressure ranging from 0.1 to 10 Torr within one chamber according to an ALD process such that the dielectric film 20 is composed of the composite dielectric of the SrTiO3 film and the anti-crystallization film has a thickness of 20 to 200 Å. The dielectric film 20 is composed of the composite dielectric of the SrTiO3 film and the Al2O3 film is deposited at a temperature ranging form 200 to 500° C. The dielectric film 20 is composed of the composite dielectric of the SrTiO3 film and the SiO2 film is deposited at a temperature ranging from 25 to 500° C.

On one hand, in forming the dielectric film 20 composed of the composite dielectric of the SrTiO3 film and the Al2O3 film according to the ALD process, the dielectric film 20 is deposited by repeatedly performing a SrO thin film deposition cycle x including a Sr source gas flowing step, a purging step, a reaction gas flowing step and a purging step, a TiO2 thin film deposition cycle y including a Ti source gas flowing step, a purging step, a reaction gas flowing step and a purging step, and an Al2O3 thin film deposition cycle z including an Al source gas flowing step, a purging step, a reaction gas flowing step and a purging step, in such a manner that the z cycle and the (x+y) cycle are alternately repeated after the SrTiO3 thin film is deposited through the (x+y) cycle, or the (x+y) cycle and the z cycle are alternately repeated after the Al2O3 thin film is deposited through the z cycle.

On the other hand, in forming the dielectric film 20 composed of the composite dielectric of the SrTiO3 film and the SiO2 film is deposited by repeatedly performing a SrO thin film deposition cycle x′ including a Sr source gas flowing step, a purging step, a reaction gas flowing step and a purging step, a TiO2 thin film deposition cycle y′ including a Ti source gas flowing step, a purging step, a reaction gas flowing step and a purging step, and an SiO2 thin film deposition cycle z including an Si source gas flowing step, a purging step, a reaction gas flowing step and a purging step, in such a manner that the z′ cycle and the (x′+y′) cycle are alternately repeated after the SrTiO3 thin film is deposited through the (x′+y′) cycle, or the (x′+y′) cycle and the z cycle are alternately repeated after the SiO2 thin film is deposited through the z′ cycle.

Here, each of the (x+y ) cycle, the z cycle, the (x′+y′) cycle and the z′ cycle may be repeated one to five times.

Also, Sr(thd)2THF2 is used as the Sr source gas, Ti(OiPr)4 or Ti(EtO)4 is used as the Ti source gas, and N2 or Ar is used as the purging gas. At this time, the Sr source gas, the Ti source gas and the purging gas are flowed for 0.1 to 10 seconds, respectively.

On one hand, in the Al2O3 thin film deposition cycle, Al(CH3)3(Tri-Methyl Aluminum: TMA) is used as the Al source gas, and any one selected from the group composed of O3, plasma O2 and H2O vapor is used as the reaction gas. At this time, the Al source gas is flowed for 0.1 to 5 seconds, and the reaction gas is flowed for 0.1 to 10 seconds.

On the other hand, in the SiO2 thin film deposition cycle, SiCl4(Tetra-Chloride Silicon: TCS) or Si2Cl6(Hexa-Chloro Disilane: HCD) is used as the Si source gas, and H2O vapor is used as the reaction gas. At this time, the Si source gas and the reaction gas are flowed for 0.1 to 10 seconds, respectively.

FIG. 3 illustrates a view for explaining a process of depositing the dielectric film 20 composed of the SrTiO3 film and the anti-crystallization film, which is the case where the Al2O3 film is used as the anti-crystallization film. As illustrated in FIG. 3, the deposition of the SrTiO3 film and the Al2O3 film is performed in a manner of repeating a deposition cycle, in which source gas flowing, purging, reaction gas flowing, and purging are carried out in sequence, until a thin film with desired thickness is obtained.

By forming a dielectric film composed of a composite dielectric of a SrTiO3 film and an Al2O3 film or a SiO2 film as stated above, the present invention can prevent the crystallization of the SrTiO3 film, and thus effectively prevent the problem of occurrence of leakage current from being caused by the crystallization of the SrTiO3 film.

Moreover, the present invention simplifies the thin film deposition process by using not two chambers but one chamber during the deposition of the SrTiO3 film and the anti-crystallization film, which results in improved productivity and low investment cost for equipment.

Meanwhile, the method for forming a capacitor according to the present invention may further comprise an O3 treatment step and a purging step for the deposited film, which are performed whenever each deposition cycle (x, y, z, x′, y′ or z′ cycle) terminates during the dielectric film deposition step. At this time, the O3 treatment is performed for 0.1 to 10 seconds, and the purging step is performed in a manner of flowing N2 or Ar gas for 0.1 to 5 seconds.

Through the additional O3 treatment, impurities such as carbon in the dielectric film are removed, and thus the electrical characteristics of the dielectric film can be improved. Also, since the additional O3 treatment can take the place of subsequent heat treatment, the subsequent heat treatment for the dielectric film need not be performed, as a result of which improved productivity and production cost saving can be obtained.

In addition, the method for forming a capacitor according to the present invention may further comprises an O3 treatment step and a purging step for the deposited film, which are performed whenever each unit process composed of the three deposition cycles (x, y and z cycles or x′, y′ and z′ cycles) terminates during the dielectric film deposition step. At this time, the O3 treatment is performed for 5 to 300 seconds, and the purging step is performed in a manner of flowing N2 or Ar gas for 0.1 to 5 seconds. In this case, improvement in the quality of the dielectric film, improved productivity and production cost saving can also be obtained as stated above.

Referring to FIG. 1C, a plate electrode 30 is formed on the dielectric film 20 composed of the composite dielectric of the SrTiO3 film and the anti-crystallization film. In this way, the formation of a capacitor 40 according to the present invention, which employs the dielectric film 20 composed of the composite dielectric of the SrTiO3 film and the anti-crystallization film, is completed.

As describe above, the present invention employs a composite dielectric, in which a SrTiO3 thin film having a very high dielectric constant of 100 to 150, and an anti-crystallization film (Al2O3 thin film or SiO2 thin film) having a tendency not to be crystallized under high-temperature heat treatment conditions are laminated, as a capacitor dielectric film. Consequently, the present invention can effectively suppress the crystallization of the SrTiO3 thin film through the anti-crystallization film, thereby realizing a capacitor capable of ensuring not only a high charging capacity characteristic required for a DRAM device with a line width of 70 nm or less, but also an excellent leakage current characteristic.

Also, in the present invention, impurities such as carbon in the dielectric film are removed by additionally performing O3 treatment during dielectric film deposition, so the electrical characteristics of the dielectric film can be improved. Moreover, since the additional O3 treatment can take the place of subsequent heat treatment, the subsequent heat treatment for the dielectric film need not be performed, as a result of which improved productivity and production cost saving can be obtained.

Furthermore, in the present invention, the thin film deposition process can be simplified by using not two chambers but rather just one chamber during the deposition of the SrTiO3 film and the anti-crystallization film, which results in improved productivity and low investment cost for equipment.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method for manufacturing a capacitor of a semiconductor device, the method comprising the steps of:
preparing a semiconductor substrate to have a storage node contact;
forming a storage electrode that is connected to the storage node contact;
forming on the storage electrode, a dielectric film comprised of a composite dielectric of a SrTiO3 film and an anti-crystallization film;; and
forming a plate electrode on the dielectric film.

2. The method claimed in claim 1, wherein the dielectric film is formed in a thickness of 20 to 200 Å.

3. The method as claimed in claim 1, wherein the SrTiO3 film and the anti-crystallization film are deposited within one chamber.

4. The method as claimed in claim 1, wherein the anti-crystallization film is an Al2O3 film or a SiO2 film.

5. The method as claimed in claim 4, wherein the dielectric film is comprised of a composite dielectric of the SrTiO3 film and the Al2O3 film is deposited at a pressure ranging from 0.1 to 10 Torr and at a temperature ranging from 200 to 500° C. according to an ALD process.

6. The method as claimed in claim 5, wherein the dielectric film is comprised of a composite dielectric of the SrTiO3 film and the Al2O3 film is deposited by repeatedly performing a SrO thin film deposition cycle x including a Sr source gas flowing step, a purging step, a reaction gas flowing step and a purging step, a TiO2 thin film deposition cycle y including a Ti source gas flowing step, a purging step, a reaction gas flowing step and a purging step, and an Al2O3 thin film deposition cycle z including an Al source gas flowing step, a purging step, a reaction gas flowing step and a purging step, according to the ALD process, in such a manner that the z cycle and the (x+y) cycle are alternately repeated after the SrTiO3 thin film is deposited through the (x+y) cycle, or the (x+y) cycle and the z cycle are alternately repeated after the Al2O3 thin film is deposited through the z cycle.

7. The method as claimed in claim 6, wherein each of the (x+y ) cycle, the z cycle, the (x′+y′) cycle and the z′ cycle is repeated one to five times.

8. The method as claimed in claim 6, wherein Sr(thd)2THF2 is used as the Sr source gas, Ti(OiPr)4 or Ti(EtO)4 is used as the Ti source gas, and N2 or Ar is used as the purging gas.

9. The method as claimed in claim 6, wherein the Sr source gas, the Ti source gas and the purging gas are flowed for 0.1 to 10 seconds, respectively.

10. The method as claimed in claim 6, wherein in the Al2O3 thin film deposition cycle, Al(CH3)3(Tri-Methyl Aluminum: TMA) is used as the Al source gas, and any one selected from the group comprising O3, plasma O2 and H2O vapor is used as the reaction gas.

11. The method as claimed in claim 6, wherein the Al source gas is flowed for 0.1 to 5 seconds, and the reaction gas is flowed for 0.1 to 10 seconds.

12. The method as claimed in claim 6, further comprising an O3 treatment step and a purging step for the deposited film, which are performed whenever each deposition cycle terminates during the dielectric film deposition step.

13. The method as claimed in claim 12, wherein the O3 treatment is performed for 0.1 to 10 seconds.

14. The method as claimed in claim 12, wherein the purging step is performed in a manner of flowing N2 or Ar gas for 0.1 to 5 seconds.

15. The method as claimed in claim 6, further comprising an O3 treatment step and a purging step for the deposited film, which are performed whenever each unit process comprising the three deposition cycles terminates during the dielectric film deposition step.

16. The method as claimed in claim 15, wherein the O3 treatment is performed for 5 to 300 seconds.

17. The method as claimed in claim 15, wherein the purging step is performed in a manner of flowing N2 or Ar gas for 0.1 to 5 seconds.

18. The method as claimed in claim 4, wherein the dielectric film is comprised of a composite dielectric of the SrTiO3 film and the SiO2 film is deposited at a pressure ranging from 0.1 to 10 Torr and at a temperature ranging from 25 to 500° C. according to an ALD process.

19. The method as claimed in claim 18, wherein the dielectric film is comprised of a composite dielectric of the SrTiO3 film and the SiO2 film is deposited by repeatedly performing a SrO thin film deposition cycle x′ including a Sr source gas flowing step, a purging step, a reaction gas flowing step and a purging step, a TiO2 thin film deposition cycle y′ including a Ti source gas flowing step, a purging step, a reaction gas flowing step and a purging step, and an SiO2 thin film deposition cycle z including an Si source gas flowing step, a purging step, a reaction gas flowing step and a purging step, according to the ALD process, in such a manner that the z′ cycle and the (x′+y′) cycle are alternately repeated after the SrTiO3 thin film is deposited through the (x′+y′) cycle, or the (x′+y′) cycle and the z cycle are alternately repeated after the SiO2 thin film is deposited through the z′ cycle.

20. The method as claimed in claim 19, wherein each of the (x+y ) cycle, the z cycle, the (x′+y′) cycle and the z′ cycle is repeated one to five times.

21. The method as claimed in claim 19, wherein Sr(thd)2THF2 is used as the Sr source gas, Ti(OiPr)4 or Ti(EtO)4 is used as the Ti source gas, and N2 or Ar is used as the purging gas.

22. The method as claimed in claim 19, wherein the Sr source gas, the Ti source gas and the purging gas are flowed for 0.1 to 10 seconds, respectively.

23. The method as claimed in claim 19, wherein in the SiO2 thin film deposition cycle, SiCl4(Tetra-Chloride Silicon: TCS) or Si2Cl6(Hexa-Chloro Disilane: HCD) is used as the Si source gas, and H2O vapor is used as the reaction gas.

24. The method as claimed in claim 19, wherein the Si source gas and the reaction gas are flowed for 0.1 to 10 seconds, respectively.

25. The method as claimed in claim 19, further comprising an O3 treatment step and a purging step for the deposited film, which are performed whenever each deposition cycle terminates during the dielectric film deposition step.

26. The method as claimed in claim 25, wherein the O3 treatment is performed for 0.1 to 10 seconds.

27. The method as claimed in claim 25, wherein the purging step is performed in a manner of flowing N2 or Ar gas for 0.1 to 5 seconds.

28. The method as claimed in claim 19, further comprising an O3 treatment step and a purging step for the deposited film, which are performed whenever each unit process is comprised of the three deposition cycles terminates during the dielectric film deposition step.

29. The method as claimed in claim 28, wherein the O3 treatment is performed for 5 to 300 seconds.

30. The method as claimed in claim 28, wherein the purging step is performed in a manner of flowing N2 or Ar gas for 0.1 to 5 seconds.

31. A semiconductor device formed to have a capacitor, said semiconductor device being comprised of:
a storage node contact;
a storage electrode that is connected to the storage node contact;
a dielectric film on the storage electrode, said dielectric film being comprised of a composite dielectric of a SrTiO3 film and an anti-crystallization film;; and
a plate electrode on the dielectric film.

32. The semiconductor device as claimed in claim 31, wherein the anti-crystallization film is an Al2O3 film or a SiO2 film.
